(19) United States
(12) Patent Application Publication
(10) Pub. No.: US 2025/0257450 A1
(43) Pub. Date: Aug. 14, 2025

(54) BARRIER COATINGS FOR ONE OR MORE OXIDIZING SUBSTANCES

(71) Applicant: Sierra Space Corporation, Louisville, CO (US)

(72) Inventor: John William Janzen, Waunakee, WI (US)

(21) Appl. No.: 19/046,204

(22) Filed: Feb. 5, 2025

Related U.S. Application Data
(60) Provisional application No. 63/552,989, filed on Feb. 13, 2024.

(51) Int. Cl. C23C 16/24; B65D 25/14; C03C 17/22; C23C 16/34

(52) U.S. Cl. CPC C23C 16/24; B65D 25/14; C03C 17/225; C23C 16/345; C03C 2217/281; C03C 2218/1525

(57) ABSTRACT

Barrier coatings for one or more oxidizing substances are disclosed herein. Coated articles, coated containers, engine systems, reactors, methods of making a coated article, and methods for storing one or more oxidizing substances are also disclosed herein. In one exemplary implementation, a coated article having a substrate and a barrier coating, where the barrier coating include hydrogen-terminated silicon is disclosed.

### CROSS REFERENCE TO RELATED APPLICATIONS

This application claims the benefit of U.S. Provisional Patent Application No. 63/552,989 filed Feb. 13, 2024, the content of which is incorporated herein by reference.

### TECHNICAL FIELD

The subject matter described herein relates to barrier coatings and articles coated with the same.

### BACKGROUND

Oxidizing substances (e.g., hydrogen peroxide (H₂O₂), hydroxylamine nitrate, etc.) have many uses. For example, hydrogen peroxide can be used as source of chemical energy in rocket engines and thrusters. It can be used by itself, via decomposition through a catalyst to produce thrust, or it can be used as an oxidizer and combined with a fuel to provide thrust. Although hydrogen peroxide has many advantages, one of its most significant disadvantages is that it is unstable and decomposes naturally. This results in a gradual loss of potency for use in, for example, thrusters, and a limited lifetime in storage. The decomposition rate of hydrogen peroxide is increased by contact with many materials through chemical reactions that happen on the surface of the material and by materials that are leached out by and into the hydrogen peroxide. As a result, suitable materials for long-term storage and use of hydrogen peroxide are limited.

For example, certain aluminum and zirconium alloys can be used, but these special alloys are expensive, somewhat rare and have relatively low strength or other limitations. Materials like glass or some plastics do not have the strength and toughness that is desirable for certain uses, such as tank and piping materials for aerospace applications. Unfortunately the use of more common metal alloys, such as stainless steel, which can reduce the cost, complexity and time to manufacture hydrogen peroxide containing systems, ends up increasing the hydrogen peroxide decomposition rate due to surface reactions and leachate contamination. Moreover, hydrogen peroxide can be corrosive, and thus, incompatible with these more common metal alloys.

Accordingly, there remains a need for materials that are compatible with oxidizing substances, like hydrogen peroxide, to allow for more effective storage and use thereof.

### SUMMARY

In certain aspects of the current subject matter, challenges associated with storing and using mixtures of one or more oxidizing substances propellant compositions (e.g., hydrogen peroxide or hydroxylammonium (HAN)) can be addressed by inclusion of one or more of the features described herein or comparable/equivalent approaches as would be understood by one of ordinary skill in the art. Aspects of the current subject matter relate to coatings for use in oxidizing substance storage and use applications.

Exemplary coating articles are described herein. In one exemplary aspect, a coated article includes a substrate and a barrier coating disposed on at least a portion of the substrate for substantially preventing the substrate from reacting with one or more oxidizing substances, in which the barrier coating includes hydrogen-terminated silicon.

In some aspects, the one or more oxidizing substances can include hydrogen peroxide, hydroxylamine nitrate, deionized water, or any combination thereof.

In some aspects, the coated article can be a pipe, a container, a valve, a diaphragm, a sensor, a membrane, a filter, a thruster, one or more components of an engine, or one or more components of reactor, or one or more components of a storage or supply system.

In some aspects, the coated article can be part of a launch system, an aerospace vehicle, a propulsion system, a hydrogen peroxide production or storage system, or a hydroxylamine nitrate production or storage system.

In some aspects, the substrate can include one or more ceramics.

In some aspects, the substrate can include one or more polymers.

In some aspects, the substrate can include one or more metals. In one aspect, the one or more metals can include stainless steel. In other aspects, the one or more metals can include one or more metal alloys. In certain aspects, the one or more metals can include nickel alloys, zirconium alloys, or niobium alloys.

In some aspects, the substrate can include at least one glass.

In some aspects, the coated article can include a mixture. The mixture can include the hydrogen peroxide, in which the mixture is selectively stored within a housing at least partially defined by the substrate. In certain aspects, the hydrogen peroxide can be greater than or equal to 30 mass percent of the mixture. In other aspects, the hydrogen peroxide can be greater than or equal to 92 mass percent of the mixture. In another aspect, the hydrogen peroxide can be greater than or equal to 98 mass percent of the mixture. In some aspects, the mixture can be in contact with at least a portion of the barrier coating.

In some aspects, a decomposition rate of the hydrogen peroxide housed in the coating article can be equal to or less than 5 mass percent over at least 162 hours at 150° F. In certain aspects, a decomposition rate of the hydrogen peroxide housed in the coating article can be from about 0.1 mass percent to 5 mass percent over at least 162 hours at 150° F. In other aspects, a decomposition rate of the hydrogen peroxide housed in the coating article can be equal to or less than 1 mass percent over at least 162 hours at 150° F.

In some aspects, there can be no more than 0.05 ppm of silicon present in the mixture over at least 162 hours at 150° F.

In some aspects, there can be no more than 0.05 ppm of iron present in the mixture over at least 162 hours at 150° F.

In some aspects, there can be no more than 0.07 ppm of chromium present in the mixture over at least 162 hours at 150° F.

In some aspects, there can be no more than 0.05 ppm of nickel present in the mixture over at least 162 hours at 150° F.

In some aspects, the barrier coating can have a thickness from about 0.1 microns to 5 microns. In certain aspects, the barrier coating can have a thickness from about 0.2 microns to 3 microns. In other aspects, the barrier coating can have a thickness from about 0.5 microns to 1 micron. In one aspect, the barrier coating can have a thickness of about 0.9 microns.

In some aspects, the barrier coating can be formed by chemical vapor deposition.

Exemplary coating containers are described herein. In one exemplary aspect, a coating container includes a housing configured to selectively store a mixture that includes one or more oxidizing substances, in which the housing has an outer surface and an inner surface; and a barrier coating disposed onto at least a portion of the inner surface configured to contact the one or more oxidizing substances, in which the barrier coating includes hydrogen-terminated silicon.

In some aspects, the housing can include one or more ceramics.

In some aspects, the housing can include one or more polymers.

In some aspects, the housing can include one or more metals. In one aspect, the one or more metals can include one or more metal alloys. In other aspect, the one or more metals can include stainless steel. In certain aspects, the one or more metals comprise nickel alloys, zirconium alloys, or niobium alloys.

In some aspects, the housing can include at least one glass.

In some aspects, the coated container can include the mixture.

In some aspects, the one or more oxidizing substances can include hydrogen peroxide, hydroxylamine nitrate, deionized water, or any combination thereof. In certain aspects, the hydrogen peroxide can be greater than or equal to 30 mass percent of the mixture. In other aspects, the hydrogen peroxide can be greater than or equal to 92 mass percent of the mixture. In another aspect, the hydrogen peroxide can be greater than or equal to 98 mass percent of the mixture.

In some aspects, a decomposition rate of the hydrogen peroxide in the housing can be equal to or less than 5 mass percent over at least 162 hours at 150° F. In other aspects, a decomposition rate of the hydrogen peroxide in the housing can be from about 0.1 mass percent to 5 mass percent over at least 162 hours at 150° F. In certain aspects, a decomposition rate of the hydrogen peroxide in the housing can be equal to or less than 1 mass percent over at least 162 hours at 150° F.

In some aspects, there can be no more than 0.05 ppm of silicon present in the mixture over at least 162 hours at 150° F.

In some aspects, there can be no more than 0.05 ppm of iron present in the mixture over at least 162 hours at 150° F.

In some aspects, there can be no more than 0.07 ppm of chromium present in the mixture over at least 162 hours at 150° F.

In some aspects, there can be no more than 0.05 ppm of nickel present in the mixture over at least 162 hours at 150° F.

In some aspects, the barrier coating can be formed by chemical vapor deposition.

In some aspects, the barrier coating can have a thickness from about 0.1 microns to 5 microns. In certain aspects, the barrier coating can have a thickness from about 0.2 microns to 3 microns. In other aspects, the barrier coating can have a thickness from about 0.5 microns to 1 micron. In one aspect, the barrier coating can have a thickness of about 0.9 microns.

Exemplary engine systems are described herein. In one exemplary aspect, an engine system includes one or more components configured to come in contact with one or more propellants, in which the one or more propellants include one or more oxidizing substances; and a barrier coating disposed on at least a portion of the one or more components for substantially preventing the one or more components from reacting with the one or more oxidizing substances, in which the barrier coating includes hydrogen-terminated silicon.

In some aspects, the barrier coating can be disposed on an inner-most surface of the one or more components and configured to come in contact with one or more propellants.

In some aspects, the one or more propellants can include hydrogen peroxide, hydroxylamine nitrate, deionized water, or any combination thereof.

Exemplary reactors are described herein. In one exemplary aspect, a reactor includes one or more catalyst beds with one or more catalysts; one or more base structures configured to support a respective one or more catalysts beds; and a barrier coating disposed on at least a portion of at least one of the one or more base structures for substantially preventing the one or more base structures from reacting with one or more oxidizing substances, in which the barrier coating includes hydrogen-terminated silicon.

In some aspects, the barrier coating can be deposited on a surface of the one or more base structures and configured to come in contact with the one or more oxidizing substances.

In some aspects, the one or more oxidizing substances can include hydrogen peroxide, hydroxylamine nitrate, deionized water, or any combination thereof.

In some aspects, the one or more catalysts can have a time on stream of about 30 hours.

In some aspects, the one or more catalysts can have a time on stream that is greater than a time on stream of one or more catalysts of an uncoated reactor.

Methods of making a coated article are also disclosed. In one exemplary aspect, the method includes depositing a barrier coating onto at least a portion of a substrate configured to contact an oxidizing substance, in which barrier coating includes hydrogen-terminated silicon.

In some aspects, the one or more oxidizing substances can include hydrogen peroxide, hydroxylamine nitrate, deionized water, or any combination thereof.

In some aspects, depositing the barrier coating can include placing the substrate in a chamber, heating the substrate, introducing one or more precursors and one or more inert carrier sources into the chamber to allow the precursor and source to react to thereby form the barrier coating on at least one surface of the heated substrate, in which the at least one surface can be configured to contact hydrogen peroxide.

In some aspects, the one or more precursors can include silane.

In some aspects, the one or more inert carriers can include hydrogen, helium, argon, or any combination thereof.

Methods for storing an oxidizing substance are also disclosed. In one exemplary aspect, the method includes storing or passing one or more oxidizing substances in or through a coated article, in which the coated article includes a housing having an outer surface and an inner surface, and a barrier coating disposed onto at least a portion of the inner surface, in which the barrier coating includes hydrogen-terminated silicon.

In some aspects, the one or more oxidizing substances can include hydrogen peroxide, hydroxylamine nitrate, deionized water, or any combination thereof.

In some aspects, the housing can include one or more ceramics.

In some aspects, the housing can include one or more polymers.

In some aspects, the housing comprises one or more metals. In certain aspects, the one or more metals can include one or more metal alloys. In other aspects, the one or more metals can include stainless steel. In some aspects, the one or more metals can include nickel alloys, zirconium alloys, niobium alloys, copper, or silver.

In some aspects, the housing can include at least one glass.

In some aspects, the one or more oxidizing substances can include hydrogen peroxide or hydroxylamine nitrate. In certain aspects, the hydrogen peroxide can be greater than or equal to 30 mass percent of the mixture. In other aspects, the hydrogen peroxide can be greater than or equal to 92 mass percent of the mixture. In another aspect, the hydrogen peroxide can be greater than or equal to 98 mass percent of the mixture.

In some aspects, a decomposition rate of the hydrogen peroxide in the housing can be equal to or less than 5 mass percent over at least 162 hours at 150° F. In other aspects, a decomposition rate of the hydrogen peroxide in the housing can be from about 0.1 mass percent to 5 mass percent over at least 162 hours at 150° F. In certain aspects, a decomposition rate of the hydrogen peroxide in the housing can be equal to or less than 1 mass percent over at least 162 hours at 150° F.

In some aspects, there can be no more than 0.05 ppm of silicon present in the mixture over at least 162 hours at 150° F.

In some aspects, there can be no more than 0.05 ppm of iron present in the mixture over at least 162 hours at 150° F.

In some aspects, there can be no more than 0.07 ppm of chromium present in the mixture over at least 162 hours at 150° F.

In some aspects, there can be no more than 0.05 ppm of nickel present in the mixture over at least 162 hours at 150° F.

In some aspects, the method can include depositing the barrier coating onto the inner surface of the housing. In one aspect, the housing can include a substrate, and wherein depositing the barrier coating can include placing the substrate in a chamber, heating the substrate, introducing one or more precursors and one or more inert carrier sources into the chamber to allow the precursor and source to react to thereby form the barrier coating on at least one surface of the heated substrate, in which the at least one surface can be configured to contact hydrogen peroxide.

In some aspects, the barrier coating can have a thickness from about 0.1 microns to 5 microns. In certain aspects, the barrier coating can have a thickness from about 0.2 microns to 3 microns. In other aspects, the barrier coating can have a thickness from about 0.5 microns to 1 micron. In one aspect, the barrier coating can have a thickness of about 0.9 microns.

The details of one or more implementations of the subject matter described herein are set forth in the accompanying drawings and the description below. Other features and advantages of the subject matter described herein will be apparent from the description and drawings, and from the claims. The claims that follow this disclosure are intended to define the scope of the protected subject matter.

### BRIEF DESCRIPTION OF THE DRAWINGS

The accompanying drawings, which are incorporated into and constitute a part of this specification, show certain aspects of the subject matter disclosed herein and, together with the description, help explain some of the principles associated with the disclosed implementations. In the drawings:

FIG. 1 illustrates a schematic of a coated article having a substrate and a barrier coating disposed onto at least a portion of the substrate;

FIG. 2 is a schematic cross-sectional view of a coated container having a housing and a barrier coating disposed onto at least a portion of an inner surface of the housing;

FIG. 3 is a schematic partial cross-sectional view of a portion of an engine system having one or more components with a barrier coating disposed on at least a portion thereof;

FIG. 4 is a schematic partial cross-sectional view of a system with at least one reactor having a catalyst bed supported by a base structure coated with a barrier coating;

FIG. 5 is a chart illustrating the test results of the active oxygen loss of the test samples by tubing finish and coating;

FIG. 6 is a chart illustrating the test results of the active oxygen loss of the test samples by coating;

FIG. 7 is a chart illustrating the test results of the H₂O₂ mass % of the test samples by tubing finish and coating;

FIG. 8 is a chart illustrating the test results of the H₂O₂ mass % of the test samples by coating;

FIG. 9 is a illustrates the fluid recovered from each test sample after the test period;

FIG. 10 illustrates the total silicon, chromium, iron, and nickel contamination of the test samples by tubing finish and coating;

FIG. 11 is illustrates the total silicon, chromium, iron, and nickel contamination of the test samples by tubing finish and coating;

FIG. 12 illustrates the silicon contamination of the test samples by tubing finish and coating;

FIG. 13 illustrates the silicon contamination of the test samples by coating;

FIG. 14 illustrates the iron contamination of the test samples by tubing finish and coating;

FIG. 15 illustrates the iron contamination of the test samples by coating;

FIG. 16 illustrates the chromium contamination of the test samples by tubing finish and coating;

FIG. 17 illustrates the chromium contamination of the test samples by coating;

FIG. 18 illustrates the nickel contamination of the test samples by tubing finish and coating; and

FIG. 19 illustrates the nickel contamination of the test samples by coating;

FIG. 20 illustrates an electropolished U-tube without any barrier coating;

FIG. 21 illustrates micrographs taken at different magnifications of a bottom section of the electropolished U-tube of FIG. 20;

FIG. 22 illustrates micrographs taken at different magnifications of a curved section of the electropolished U-tube of FIG. 20;

FIG. 23 illustrates an electropolished U-tube coated with a barrier coating, RD13-silicon;

FIG. 24 illustrates micrographs taken at different magnifications of a bottom section of the electropolished U-tube of FIG. 23;

FIG. 25 illustrates micrographs taken at different magnifications of a curved section of the electropolished U-tube of FIG. 23;

FIG. 26 illustrates an electropolished U-tube coated with a barrier coating, Silcolly;

FIG. 27 illustrates micrographs taken at different magnifications of a bottom section of the electropolished U-tube of FIG. 26; and

FIG. 28 illustrates micrographs taken at different magnifications of a curved section of the electropolished U-tube of FIG. 27.

When practical, similar reference numbers denote similar structures, features, or elements.

### DETAILED DESCRIPTION

Certain exemplary aspects will now be described to provide an overall understanding of the principles of the structure, function, manufacture, and use of the systems and processes disclosed herein. One or more examples of these aspects are illustrated in the accompanying drawings. Those skilled in the art will understand that the systems and processes specifically described herein and illustrated in the accompanying drawings are non-limiting exemplary aspects and that the scope of the present invention is not defined solely by the claims. The features illustrated or described in connection with one exemplary aspect may be combined with the features of other aspects. Such modifications and variations are intended to be included within the scope of the present invention.

Terminology used herein is for the purpose of describing particular aspects and implementations only and is not intended to be limiting. For example, as used herein, the singular forms “a,” “an,” and “the” are intended to include the plural forms as well, unless the context clearly indicates otherwise.

As used herein in the specification and claims, including as used in the examples and unless otherwise expressly specified, all numbers can be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value can have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical values given herein should also be understood to include about or approximately that value, unless the context indicates otherwise. For example, if the value “10” is disclosed, then “about 10” is also disclosed. Any numerical range recited herein is intended to include all sub-ranges subsumed therein. It is also understood that when a value is disclosed that “less than or equal to” the value, “greater than or equal to the value” and possible ranges between values are also disclosed, as appropriately understood by the skilled artisan. For example, if the value “X” is disclosed the “less than or equal to X” as well as “greater than or equal to X” (e.g., where X is a numerical value) is also disclosed. It is also understood that the throughout the application, data is provided in a number of different formats, and that this data, represents endpoints and starting points, and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

For purposes of describing and defining the present teachings, it is noted that unless indicated otherwise, the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Implementations of the current subject matter include methods, apparatuses, articles of manufacture, and systems relating to the storage and use of one or more oxidizing substances, for example, in the area of aerospace.

The present disclosure describes a barrier coating that is configured to allow materials in systems that use oxidizing substances to be chosen not primarily on their compatibility with such oxidizing substances, but rather on other properties such as cost, machinability, strength, etc. With the barrier coatings described herein, materials (e.g., Class 2 materials (e.g., materials having restricted compatibility with limits on time, temperature, duration due to some effects on the oxidizer and material) or 3 materials (e.g., materials having strong and possibly hazardous effects on the oxidizer and/or material) that would not otherwise be available (e.g., due to their corrosion or reactivity with one or more oxidizing substances, such as hydrogen peroxide) can be used in a greater amount of applications that involve oxidizing substances. By way of example, the barrier coatings described herein enable containers, tanks, piping and fluid flow components constructed of lower cost and less compatible materials (e.g., Class 2 or 3 materials) to successfully be used for long-term containment of one or more oxidizing substances. For applications such as spacecraft, the barrier coatings can allow for the use of materials with high strength to weight ratios or other desirable characteristics for containment or use of one or more oxidizing substances. Moreover, the barrier coatings described can allow for applications where the one or more oxidizing substances need to be maintained in a high purity state and maintain a low decomposition rate.

The barrier coatings described herein, therefore, have numerous advantages. For example, the barrier coatings can lower the decomposition rate and leachate contamination of the one or more oxidizing substances that occur from highly compatible metals and materials (e.g., Class 1 materials); provide low decomposition rates and leachate contamination of the one or more oxidizing substances when used with low compatible materials, such as stainless steel, thereby increasing the number and types of materials that can be used with one or more oxidizing substances; and reduce the surface area of the material that is in contact with the one or more oxidizing substances and thus reduce the surface area dependent decomposition rate or leachate effect thereof.

In general, the present barrier coatings include a hydrogen-terminated silicon that is coated onto at least a portion of a substrate to form a coated article. These barrier coatings substantially prevent the substrate from reacting with one or more oxidizing substances. Non-limiting examples of suitable oxidizing substances includes, hydrogen peroxide, hydroxylamine nitrate, deionized water, or any combination thereof.

In some aspects, the substrate can at least partially define a housing that a fluid can be selectively stored therein or a channel that allows a fluid pass therethrough. The fluid can be in the form of a mixture. As such, during use, the mixture is in contact with at least a portion of the barrier coating.

In such aspects, the mixture can include the hydrogen peroxide. The hydrogen peroxide can be present within the mixture at a variety of mass percent. In some aspects, the hydrogen peroxide is greater than or equal to 30 mass percent of the mixture, greater than or equal to 92 mass percent of the mixture, or greater than or equal to 98 mass percent of the mixture. It is also contemplated that the amount of hydrogen peroxide present within the mixture does not fall outside any of these recited ranges. It is further contemplated that the amount of hydrogen peroxide present within the mixture can be between any of these recited ranges.

As discussed above, the barrier coatings described herein inhibit the substrate from reacting with one or more oxidizing substances, e.g., hydrogen peroxide. As a result, a low decomposition rate of the one or more oxidizing substances of the mixture can be maintained, which can also provide stability (e.g., at or within a desired purity state) of the one or more oxidizing substances for a longer period of time when in contact with the substrate. A low decomposition rate can be a decomposition rate, for example, that is less than 5% concentration loss of the one or more oxidizing substances of a mixture per year at room temperature. For example, a low decomposition rate of 90% concentration hydrogen peroxide would result in a hydrogen peroxide concentration of 85% after one year at room temperature (e.g., 20-25° C.). A person skilled in the art would appreciate that a low decomposition rate can depend on the end use of the one or more oxidizing substances. In certain aspects, the decomposition rate of the hydrogen peroxide is equal to or less than 5 mass percent over at least 162 hours days at 150° F. In other aspects, the decomposition rate of the hydrogen peroxide is from about 0.1 mass percent to 5 mass percent over 7 days at 150° F. In one aspect, the decomposition rate of the hydrogen peroxide in the housing is equal to or less than 1 mass percent over 7 days at 150° F. It is also contemplated that the decomposition rate of the hydrogen peroxide does not fall outside any of these recited ranges. It is further contemplated that the decomposition rate of the hydrogen peroxide can be between any of these recited ranges.

Furthermore, with inhibiting the substrate from reacting with the one or more oxidizing substances for which it is in contact with during use, the barrier coatings can minimize leaching of certain elements from the material of the substrate and into the mixture. As a result, a low contamination rate of the mixture can be effected. A low contamination rate can be a contamination rate that prevents less than 5% concentration loss of the one or more oxidizing substances of a mixture per year at room temperature (e.g., 20-25° C.). A person skilled in the art would appreciate that a low contamination rate can depend on the end use of the one or more oxidizing substances. Non-limiting examples of certain elements include silicon, iron, chromium, and nickel. A person having ordinary skill in the art would appreciate that the leachates will depend on the material(s) used to form the substrate.

In some aspects, there can be no more than 0.05 ppm of silicon present in the mixture over at least 162 hours at 150° F. In other aspects, there is from about 0.01 ppm to about 0.05 ppm, from about 0.001 ppm to about 0.015 ppm, or from about 0.001 ppm to about 0.02 ppm of silicon present in the mixture over at least 162 hours at 150°. In some aspects, there is no silicon (0 ppm) present in the mixture over at least 162 hours at 150° F. It is also contemplated that the amount of silicon present in the mixture over at least 162 hours at 150° F. does not fall outside any of these recited ranges. It is further contemplated that the amount of silicon present in the mixture over at least 162 hours at 150° F. can be between any of these recited ranges.

In some aspects, there can be no more than 0.05 ppm of iron present in the mixture over at least 162 hours at 150° F. In other aspects, there is from about 0.005 ppm to about 0.049 ppm, from about 0.001 ppm to about 0.015 ppm, or from about 0.001 ppm to about 0.02 ppm of iron present in the mixture over at least 162 hours at 150°. In some aspects, there is no iron (0 ppm) present in the mixture over at least 162 hours at 150° F. It is also contemplated that the amount of iron present in the mixture over at least 162 hours at 150° F. does not fall outside any of these recited ranges. It is further contemplated that the amount of iron present in the mixture over at least 162 hours at 150° F. can be between any of these recited ranges.

In some aspects, there can be no more than 0.07 ppm of chromium present in the mixture over at least 162 hours at 150° F. In other aspects, there is from about 0.008 ppm to about 0.064 ppm, from about 0.001 ppm to about 0.015 ppm, or from about 0.001 ppm to about 0.02 ppm of chromium present in the mixture over at least 162 hours at 150°. In some aspects, there is no chromium present in the mixture (0 ppm) over at least 162 hours at 150° F. It is also contemplated that the amount of chromium present in the mixture over at least 162 hours at 150° F. does not fall outside any of these recited ranges. It is further contemplated that the amount of chromium present in the mixture over at least 162 hours at 150° F. can be between any of these recited ranges.

In some aspects, there can be no more than 0.05 ppm of nickel present in the mixture over at least 162 hours at 150° F. In other aspects, there is from about 0.01 ppm to about 0.05 ppm, from about 0.001 ppm to about 0.015 ppm, or from about 0.001 ppm to 0.02 ppm of nickel present in the mixture over at least 162 hours at 150°. In some aspects, there is no nickel present in the mixture (0 ppm) over at least 162 hours at 150° F. It is also contemplated that the amount of nickel present in the mixture over at least 162 hours at 150° F. does not fall outside any of these recited ranges. It is further contemplated that the amount of nickel present in the mixture over at least 162 hours at 150° F. can be between any of these recited ranges.

The substrate can be formed of a variety of materials. In some aspects, the substrate can includes one or more ceramics. Alternatively, or in addition, the substrate can include one or more polymers. Alternatively, or in addition, the substrate can includes one or more metals. Alternatively, or in addition, the substrate can include at least one glass. In certain aspects, the substrate can include a combination of one or more polymers and one or more metals. In some aspects, the substrate can include a combination fluorinated polymers and alloys of aluminum, zirconium, stainless steels, tantalum, and/or niobium.

In aspects where the substrate includes at least one or more metals, the one or more metals can includes one or more metal alloys (e.g., nickel alloys, zirconium alloys, niobium alloys). Alternatively, or in addition, the one or more metals can include stainless steel (e.g., 316 stainless steel).

The barrier coating can be applied to the substrate using any known suitable method. Non-limiting examples of suitable methods include a vapor deposition method (e.g., physical vapor deposition, sputtering, organo-metallic chemical vapor deposition, chemical vapor deposition, and the like). In certain aspects, the vapor deposition method can be chemical vapor depositions. For example, in one aspect, a method of making a coated article can include depositing a barrier coating onto at least a portion of a substrate configured to contact an oxidizing substance, the barrier coating comprising hydrogen-terminated silicon. In certain aspects, depositing the barrier coating includes placing the substrate in a chamber, heating the substrate, introducing one or more precursors and one or more inert carrier sources into the chamber to allow the precursor and source to react to thereby form the barrier coating on at least one surface of the heated substrate, the at least one surface configured to contact hydrogen peroxide. While the one or more precursors can be any suitable precursor, in one aspect the one or more precursors include silane. While the one or more inert carriers can be any suitable carrier, in one aspects, the one or more inert carriers include hydrogen, helium, argon, or any combination thereof.

The barrier coating can have a variety of configurations. In some aspects, the barrier coating can have a thickness that is equal to or less than 1 microns. In other aspects, the thickness of the barrier coating can be from about has a thickness from about 0.1 microns to 5 microns, from about 0.2 microns to 3 microns, or from about 0.5 microns to 1 microns. It is also contemplated that the thickness of the barrier coating does not fall outside any of these recited ranges. It is further contemplated that the thickness of the barrier coating can be between any of these recited ranges. In one aspect, wherein the barrier coating can have a thickness of about 0.9 microns.

The present barrier coatings disclosed herein can be used in a wide variety of applications that involve the use or storage of one or more oxidizing substances. For example, in some aspects, a method for storing an oxidizing substance can include storing or passing one or more oxidizing substances in or through a coated article. The coated article can include a housing having an outer surface and an inner surface, and a barrier coating disposed onto at least a portion of the inner surface, where the barrier coating can include hydrogen-terminated silicon.

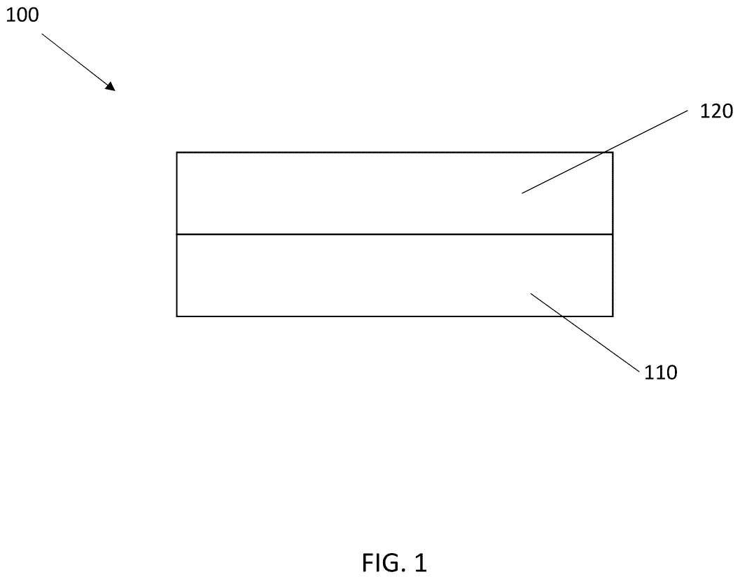

FIG. 1 illustrates an exemplary coated article 100. As shown, the coated article 100 include a substrate 110 and a barrier coating 120 that is disposed on at least a portion of the substrate 110, where the barrier coating 120 includes a hydrogen-terminated silicon. The coated article can have a variety of configurations. In some aspects, the coated article can be a pipe, a container, a valve, a diaphragm, a sensor, a membrane, a filter, a thruster, or one or more components of an engine (e.g., a rocket engine), or one or more components of a reactor, or one or more components of a storage or supply system. Alternatively, or in addition, the coated article can be part of a launch system, an aerospace vehicle, a propulsion system, or a production or storage system for one or more oxidizing substances (e.g., a hydrogen peroxide production or storage system, or a hydroxylamine nitrate production or storage system).

Further, in some aspects, the barrier coating can have a substantially uniform thickness, e.g., as shown in FIG. 1. In other aspects, the barrier coating can have a variable thickness. In aspects where more than one portion of the substrate is coated with the barrier coating, all the barrier coatings can have a substantially uniform thickness, or at least one barrier coating has a thickness that is different than another barrier coating of the coated article.

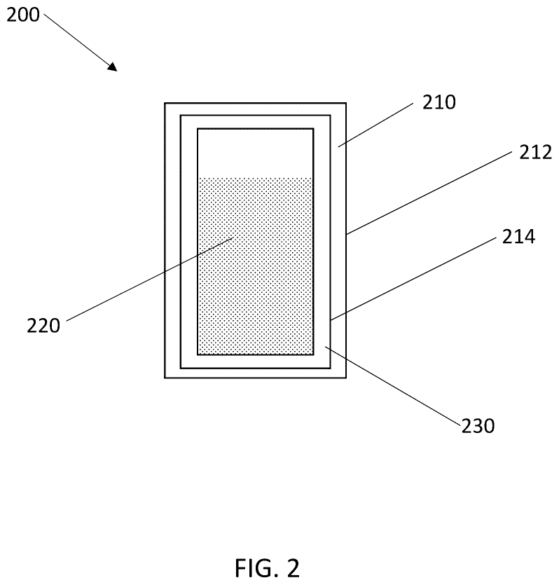

In some aspects, the coated article can be a coated container for storing one or more oxidizing substances. A cross-sectional view of an exemplary coated container 200 is illustrated in FIG. 2. As shown, the coated container 200 includes a housing 210 configured to selectively store a mixture 220 that includes one or more oxidizing substances, and a barrier coating 230 that includes a hydrogen-terminated silicon. At least one or more components of the housing can be formed of a substrate, e.g., substrate 110 shown in FIG. 1, and therefore unless otherwise noted, the foregoing discussion with respect to a substrate is also applicable to the housing 210.

The housing can have a variety of configurations. In some aspects, as illustrated, the housing 210 has an outer surface 212 and an inner surface 214, in which the inner surface 214 is configured to contact the mixture 220. Further, a barrier coating 230 is disposed onto at least a portion of the inner surface 212. As such, during use, the barrier coating 230 is in direct contact with the mixture 220, thereby preventing the coating portions of the inner surface 214 from coming into direct contact with the mixture 220. As a result, the decomposition rate of the one or more oxidizing substances of the mixture and the reactivity of the housing material with the one or more oxidizing substances can be minimized. While not shown, it is also contemplated herein that in other aspects, the entire inner surface can be coated with the barrier coating.

While the housing 210 in FIG. 2 is illustrated as an enclosed housing, in some aspects, the housing can be open (e.g., top-end and/or bottom-end open) and one or more lids can be used to enclose the housing, and thus the mixture contained therein. In such instances, the inner surface of the one or more lids can also be coated with the barrier coating. In FIG. 2, while the entire inner surface 214 is coated with the barrier coating, in other aspects, one or more portions of the inner surface could be coated. For example, only the portion of the inner surface that is defined below a fill-line of the coated container can be coated.

Further, in some aspects, the barrier coating can have a substantially uniform thickness, e.g., as shown in FIG. 2. In other aspects, the barrier coating can have a variable thickness. In aspects where more than one portion of the inner surface is coated with the barrier coating, all the barrier coatings can have a substantially uniform thickness, or at least one barrier coating has a thickness that is different than another barrier coating of the coated container.

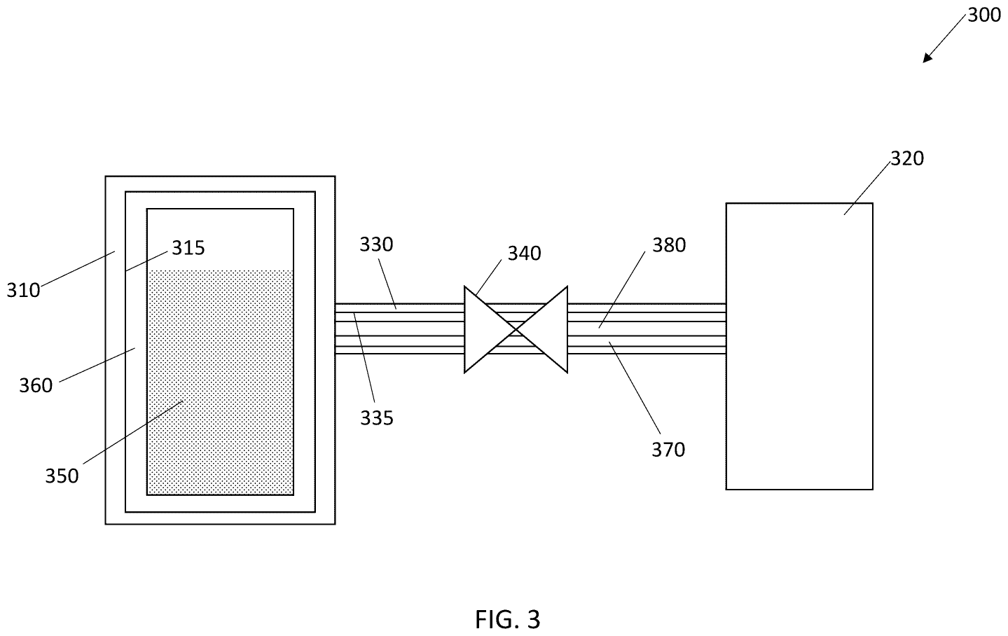

FIG. 3 illustrates an exemplary engine system 300 (e.g., a rocket engine). As shown, the engine system includes at least two components 310, 320 that are in fluid communication via a tube 330 and includes a valve 340 positioned along the tube 330. In this illustrated aspect, the two components includes a reservoir housing 310 (e.g., a tank) for storing one or more propellants 350 (e.g., one or more oxidizing substances) and a combustion chamber 320. The reservoir housing 310 is illustrated in a cross-sectional view to illustrate a first barrier coating 360 disposed on the inner-most surface 315 of the reservoir housing 310 and the one or more propellants 350 in contact with at least a portion of the first barrier coating 360.

While the reservoir housing 310 in FIG. 3 is illustrated as an enclosed housing, in some aspects, the housing can be open (e.g., top-end and/or bottom-end open) and one or more lids can be used to enclose the housing, and thus the one or more propellants contained therein. In such instances, the inner surface of the one or more lids can also be coated with the same or different barrier coating. In FIG. 3, while the entire inner-most surface 315 is coated with the barrier coating, in other aspects, one or more portions of the inner surface could be coated. For example, only the portion of the inner-most surface that is defined below a fill-line of the reservoir housing container can be coated. It is also contemplated herein that the reservoir housing is the only component of the engine system 300 that is coated with a barrier coating.

Alternatively, or in addition, the tube 330 and/or valve 340 can be coated with a barrier coating that is the same or different than the barrier coating disposed on the inner-most surface of the reservoir housing. In FIG. 3, the tube 330 is shown in a cross-sectional view illustrating a second barrier coating 370 disposed on the inner-most surface 335 of the tube, thereby defining a channel 380 extending therethrough. In use, this channel 380, in combination with the valve 340 when open, allows the one or more propellants 350 to be transferred (e.g., via a pump or by a source of pressure or acceleration) from the reservoir housing 310 into the combustion chamber 320. It is also contemplated herein that only the tube is coated with the first barrier coating, and the reservoir housing and/or valve is not coated with a barrier coating.

While other components of an engine system are not illustrate in FIG. 3, a person having ordinary skill in the art would appreciate that one or more of the other components could be coated with a barrier coating.

Further, in some aspects, the first barrier coating and the second barrier can each have a respective substantially uniform thickness, e.g., as shown in FIG. 3. In other aspects, the first barrier coating and/or the second barrier coating can have a variable thickness. In aspects where more than one portion of the reservoir housing and/or tube are coated with a respective barrier coating, all the barrier coatings can have a substantially uniform thickness, or at least one barrier coating has a thickness that is different than another barrier coating of the reservoir housing and/or tube. In such aspects, all the barrier coatings can be the same or at least one barrier coating can be different relative to the other barrier coating(s) of the reservoir housing and/or the tube.

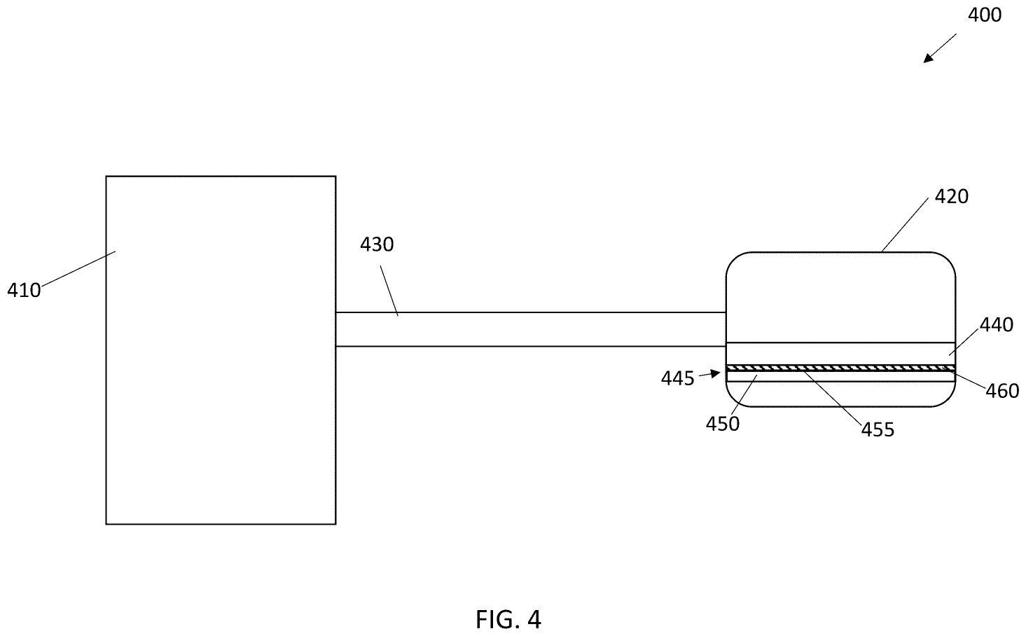

FIG. 4 illustrates an exemplary system 400 with a reservoir housing 410 (e.g., a tank) and at least one reactor 420 in fluid communication therewith via a pipe 430. The reservoir housing 410 is configured to selectively store one or more oxidizing substances (not shown) that is to be transferred through the pipe 430 to the at least one reactor 420. Once the one or more oxidizing substances is transferred to the at least one reactor 420, the substances then travel over a catalyst bed 440, which in this illustrated aspect is supported by a coated base structure 445. While not shown, the catalyst bed 440 includes one or more catalysts impregnated therein.

The coated base structure can have a variety of configurations. As shown in FIG. 4, the coated base structure 445 includes a base 450 and a barrier coating 460 disposed on at least a portion thereof. More specifically, the barrier coating 460 is deposited on a top-most surface 455 of the base structure 450 and is configured to come in contact with the one or more oxidizing substances. While not shown, the catalyst bed includes one or more catalysts impregnated therein.

With the implementation of the barrier coating, during use, the one or more catalysts have a time on stream that is greater than a time on stream of one or more catalysts of an uncoated reactor (e.g., the same reactor without the barrier coating). In some aspects, the one or more catalysts can have a time on stream of about 30 hours.

While the at least one reactor is illustrated as including one catalyst bed, a person having ordinary skill in the art would appreciate that the at least one reactor can include additional catalysts beds, with or without respective base structures. In instances where additional base structures are implemented, in some aspects none of these additional base structures are coated, whereas in other aspects, at least one of these additional base structures are coated with a barrier coating of the present disclosure.

Further, while only the base structure 445 is coated with the barrier coating 460 in FIG. 4, it is also contemplated herein that alternatively, or in addition, other elements/parts of a reactor can be coated with a barrier coating of the present disclosure (e.g., an inner surface of a chamber of the reactor for which the catalyst bed is disposed).

The following specific examples are intended to be illustrative and should not be construed as limiting in scope of the claims.

### Examples

Two chemical vapor deposition (CVD) coatings were tested on 316 stainless steel (316 SS) tubing to assess the effect on compatibility with high concentration hydrogen peroxide. The coatings tested were RD13-silicon nitride and Silcolly (a hydrogen terminated amorphous silicon). Coatings were supplied and applied by Silcotek Corporation using proprietary equipment and processes. These coatings were applied in the gas phase at temperatures in the few hundred degrees C. range. Coating thickness was approximately 800 nm (0.8 μm). Metrics that were evaluated for these tested tubing included H₂O₂ decomposition rates, leachates, and corrosion from exposure to 92% by mass H₂O₂ at 150° F. for 162.75 hours.

### Materials and Equipment

Deionized water (DI water): Laboratory facility deionized water, sourced from chlorinated city water, deionized via triple resin bed; not treated for particulates, organics or elemental chlorine. Resistivity >17.5 MΩ/cm.

ASTM Type I reagent grade water: Ricca Chemical catalog #R9153500-4C, meets ASTM Type I purity requirements.

Nitric acid: ACS reagent grade 70% (w/w/), J. T. Baker part #9601-34.

Hydrogen Peroxide: 91% Evonik Lot #A742112020 gallon #6 of 9, having 0.24 ppm (m/m) NO3⁻ concentration; 92% Evonik Lot #A742041321 gallon #3 of 4, having 0.23 ppm (m/m) NO3⁻ concentration.

Gallium concentration standard for TXRF: 100 ppm nominal Ga, CPI International, part #4400-100PPM191-100, Lot 1205304-1.

OmegaClean: OmegaClean Soap 10-1, OmegaClean part #Soap 10-1.

Ultrahigh Vacuum Foil (UHV foil): 0.0015 inch thick contaminant-free ultrahigh vacuum 1100 alloy aluminum foil, McMaster Carr part #4650N148.

Cleanroom Wiper: Texwipe TX1012 polyester cleanroom wiper, Texwipe part #TX1012.

Autopipette tips, 10 mL: Scientific specialties part #4530-00, polypropylene.

Sample tubes (TXRF sample preparation): Digestion vials, Environmental Express part #UC475-NL.

TXRF Sample Carriers: Sapphire, Bruker part #B-A20V21.

Water bath: Heating immersion circulator type, Cole Parmer model WBL-20LC-SSDI, RBICAL02999.

Stainless steel bath 19.5×11.5×6 inches.

Analytical balance: Mettler Toledo XPR205DR, resolution 0.01 mg, RBICAL02426.

Laboratory balance: Sartorius Practum 1102-15, resolution 0.01 g, RBICAL02803.

Refractometer: Atago RX-9000a, resolution 0.00001, 25° C. using a wavelength near the sodium D-lines, RBICAL03058.

Total X-Ray Fluorescence Spectrophotometer (TXRF): Bruker Picofox S2, Mo X-ray source, spectral range 1-15 keV for K and L lines.

Electropolished tubing: 316L SS, ½″ OD, 0.035″ wall thickness, High Purity Technology, Inc. part #05-0.5-0.035, ½″ EP 316 SMLS; TUBE 0.035W 10RA, Heat #561379; measured internal average surface roughness (Ra) along the tube major axis: 4.78 pin, standard deviation: 0.58.

Standard tubing (mill finish): Smooth-Bore Seamless 316 SS Tubing, ½″ OD, 0.035″ wall thickness, McMaster Carr part number 89785K844, ASTM A213, ASTM A269; measured internal average surface roughness (Ra) along the tube major axis: 32.38 μin, standard deviation: 0.07.

Chemical Vapor Deposition Coatings (CVD): Hydrogenated amorphous silicon, 180-800 nm thick; RD13 silicon nitride, <1000 nm thick; Each provided by Silcotek Corporation, Bellefonte, PA.

### Experimental Design:

The experiment design included 8 uncoated tubes (4 samples with an electropolish finish; 4 samples without any finish) and 8 CVD coated tubes with an electropolish finish (4 coated with RD13-silicon nitride and 4 coated with Silcolly). There were no mill finish splits with the CVD coatings because the coatings require an electropolished surface.

### Sample Preparation:

U-tubes having a dimension of approximately 9 inches per straight segment were fabricated out of the electropolished and standard mill finish tubing listed above, using hand-bending equipment. All cuts were made with a hand-operated rotary pipe cutter. The cut ends were inside-chamfered and deburred with a high speed steel countersink bit, chucked into a power drill. Tubes were vibratory-engraved with letters in two locations on the outer surface near the open ends of the tube in order to identify them.

After fabrication, all tubes were flushed with DI water, then cleaned by fully submerging in an ultrasonic bath at 60° C. for 20 minutes using a solution of Omegaclean diluted to the manufacturer's instructions with DI water. After the ultrasonic cleaning, the tubing was rinsed with DI water and then received a final rinse in reagent grade water. The tubes were immediately taken through a passivation process that included filling the inside of the tubes with 70% reagent grade nitric acid at room temperature (25° C.) and allowing them to stand for 3-4 hours, followed by a flowing DI water rinse and a final rinse with reagent grade water. After the acid treatment and rinses, the tubes were placed in an inverted position in a convection oven and baked in air at 225° C. for 3-4 hours. After cooling in air, the tubes were double-bagged in polyethylene zip-seal bags and either sent to Silcotek for CVD coating or held at Sierra Space so that all tubes could be prepared for H₂O₂ filling at the same time.

Upon receipt of the CVD coated tubes from Silcotek, all of the tubes in the experiment were removed from their plastic bags and conditioned at room temperature (25° C.) for 24 hours by filling them completely with 35% (w/w) H₂O₂, that was prepared by diluting 91% material from Evonik using reagent grade water. After the conditioning period, the tubes were emptied, rinsed with DI water and given a final rinse with reagent grade water. Finally, the tubes were placed in an inverted position in a convection oven and baked in air at 80° C. for about 2 hours to dry them. After drying they were allowed to cool in the oven.

Each tube was weighed to a resolution of 0.01 g, then an aliquot of 30 mL of 92% H₂O₂ was placed in each tube via three 10 mL additions from an autopipette. The weight of the H₂O₂ aliquot was recorded for each tube to a resolution of 0.01 g. Each open end of the U-tube was semi-sealed by tightly capping with a 1.5×1.5 inch square piece UHV aluminum foil, using finger-pressure to conform the foil to the tube. The tubes were chosen in random order for the weighing, filling and foil sealing operations.

The initial refractive index of the H₂O₂ was measured by taking 5 samples from the supply bottle that was used to fill the tubes. This was converted to weight % concentration per SSGD231410 Hydrogen Peroxide Refractive Index to Concentration Standardization, as outlined below:

Equation for converting refractive index measurement to mass percent H₂O₂ for binary mixtures of H₂O₂ and water:

$$Mass \% H 2 O 2 = - 3540.22 \cdot {n}^{2} + 11041 \text{.175} \cdot n - 8426.46$$

wherein n=refractive index at 25° C. using the sodium D line wavelength

This equation is derived from data from Table III, reproduced below (source: Giguere, Paul A., Geoffrion, Pierre. “Refractive Index of Hydrogen Peroxide Solutions. A Revision,” Canadian Journal of Research, Vol. 27b No. 3, March 1949. https://doi.org/10.1139/cjr49b-020.)

TABLE III
REFRACTIVE INDEX OF AQUEOUS SOLUTIONS
OF HYDROGEN PEROXIDE AT 25° C.

| H₂O₂ | | | | | | |
|---|---|---|---|---|---|---|
| % | | 0.0 | 0.2 | 0.4 | 0.6 | 0.8 |
| 0 | 1.3 | 325 | 326 | 327 | 328 | 329 |
| 1 | | 331 | 333 | 334 | 335 | 336 |
| 2 | | 338 | 339 | 340 | 341 | 343 |
| 3 | | 344 | 345 | 347 | 348 | 349 |
| 4 | | 350 | 352 | 353 | 354 | 355 |
| 5 | | 357 | 358 | 359 | 360 | 362 |
| 6 | | 363 | 364 | 365 | 367 | 368 |
| 7 | | 369 | 370 | 372 | 373 | 374 |
| 8 | | 376 | 377 | 378 | 379 | 381 |
| 9 | | 382 | 383 | 384 | 386 | 387 |
| 10 | | 388 | 389 | 391 | 392 | 393 |
| 11 | | 395 | 396 | 397 | 398 | 400 |
| 12 | | 401 | 402 | 404 | 405 | 406 |
| 13 | | 407 | 409 | 410 | 411 | 412 |
| 14 | | 414 | 415 | 416 | 418 | 419 |
| 15 | | 420 | 421 | 423 | 424 | 425 |
| 16 | | 427 | 428 | 429 | 430 | 432 |
| 17 | | 433 | 434 | 436 | 437 | 438 |
| 18 | | 439 | 441 | 442 | 443 | 444 |
| 19 | | 446 | 447 | 448 | 450 | 451 |
| 20 | | 452 | 453 | 455 | 457 | 458 |
| 21 | | 459 | 460 | 462 | 463 | 464 |
| 22 | | 466 | 467 | 468 | 470 | 471 |
| 23 | | 472 | 474 | 475 | 476 | 478 |
| 24 | | 479 | 480 | 482 | 483 | 484 |
| 23 | | 486 | 487 | 488 | 490 | 491 |
| 26 | 1.3 | 492 | 494 | 495 | 496 | 498 |
| 27 | | 409 | 500 | 502 | 503 | 504 |
| 28 | | 506 | 507 | 508 | 510 | 511 |
| 29 | | 512 | 514 | 515 | 516 | 518 |
| 30 | | 519 | 520 | 522 | 523 | 525 |
| 31 | | 526 | 527 | 529 | 530 | 532 |
| 32 | | 533 | 534 | 536 | 537 | 539 |
| 33 | | 540 | 541 | 543 | 544 | 546 |
| 34 | | 547 | 548 | 550 | 551 | 553 |
| 35 | | 554 | 555 | 557 | 558 | 560 |
| 36 | | 561 | 562 | 564 | 565 | 567 |
| 37 | | 568 | 560 | 571 | 572 | 574 |
| 38 | | 575 | 576 | 578 | 579 | 581 |
| 39 | | 582 | 583 | 585 | 586 | 588 |
| 40 | | 589 | 590 | 592 | 593 | 595 |
| 41 | | 596 | 598 | 599 | 600 | 602 |
| 42 | | 603 | 605 | 606 | 608 | 609 |
| 43 | | 611 | 612 | 613 | 615 | 616 |
| 44 | | 618 | 619 | 621 | 622 | 623 |
| 45 | | 625 | 626 | 628 | 629 | 631 |
| 46 | | 632 | 633 | 635 | 636 | 638 |
| 47 | | 639 | 641 | 642 | 643 | 645 |
| 48 | | 656 | 648 | 649 | 651 | 652 |
| 49 | | 653 | 655 | 656 | 658 | 659 |
| 50 | | 661 | 662 | 663 | 665 | 666 |
| 51 | | 668 | 659 | 671 | 672 | 674 |
| 52 | 1.3 | 675 | 617 | 678 | 680 | 681 |
| 53 | | 683 | 684 | 686 | 687 | 688 |
| 54 | | 690 | 691 | 693 | 694 | 696 |
| 55 | | 698 | 699 | 700 | 702 | 703 |
| 56 | | 705 | 706 | 707 | 709 | 711 |
| 57 | | 712 | 713 | 715 | 716 | 718 |
| 58 | | 719 | 721 | 722 | 724 | 725 |
| 59 | | 727 | 728 | 730 | 731 | 733 |
| 60 | | 734 | 736 | 737 | 739 | 740 |
| 61 | | 742 | 744 | 745 | 747 | 748 |
| 62 | | 750 | 752 | 753 | 755 | 756 |
| 63 | | 758 | 760 | 761 | 763 | 764 |
| 64 | | 766 | 768 | 769 | 771 | 772 |
| 65 | | 774 | 776 | 777 | 779 | 780 |
| 66 | | 782 | 784 | 785 | 787 | 788 |
| 67 | | 790 | 792 | 793 | 795 | 796 |
| 68 | | 798 | 800 | 801 | 803 | 804 |
| 69 | | 806 | 808 | 800 | 811 | 812 |
| 70 | | 814 | 816 | 817 | 819 | 820 |
| 71 | | 822 | 824 | 825 | 827 | 828 |
| 72 | | 830 | 832 | 833 | 835 | 836 |
| 73 | | 838 | 840 | 841 | 843 | 844 |
| 74 | | 846 | 848 | 840 | 851 | 852 |
| 75 | | 854 | 856 | 857 | 859 | 860 |
| 76 | 1.3 | 862 | 864 | 865 | 867 | 868 |
| 77 | | 870 | 872 | 873 | 875 | 876 |
| 78 | | 878 | 880 | 881 | 883 | 884 |
| 79 | | 886 | 888 | 889 | 891 | 892 |
| 80 | | 894 | 896 | 897 | 899 | 901 |
| 81 | | 903 | 904 | 906 | 908 | 909 |
| 82 | | 911 | 913 | 915 | 916 | 918 |
| 83 | | 920 | 921 | 923 | 925 | 927 |
| 84 | | 928 | 930 | 932 | 933 | 935 |
| 85 | | 937 | 939 | 940 | 942 | 944 |
| 86 | | 945 | 947 | 949 | 950 | 952 |
| 87 | | 954 | 956 | 957 | 959 | 961 |
| 88 | | 962 | 964 | 966 | 968 | 969 |
| 89 | | 971 | 973 | 974 | 976 | 978 |
| 90 | | 880 | 981 | 983 | 985 | 986 |
| 91 | | 988 | 990 | 992 | 993 | 995 |
| 92 | | 997 | 999 | *000 | *002 | *004 |
| 93 | 1.4 | 006 | 007 | 009 | 011 | 013 |
| 94 | | 014 | 016 | 018 | 020 | 021 |
| 95 | | 023 | 025 | 027 | 028 | 030 |
| 96 | | 032 | 034 | 035 | 037 | 039 |
| 97 | | 041 | 042 | 044 | 046 | 048 |
| 98 | | 049 | 051 | 053 | 055 | 056 |
| 99 | | 058 | 060 | 062 | 063 | 065 |
| 100 | 1.4 | 067 | | | | |

The tubes were then placed in the water bath located in a fume hood with the hood exhaust running.

Initially the water bath was at room temperature (25° C.). Each tube was secured in a vertical position using laboratory-type 90-degree stainless steel rod clamps. When all tubes were installed in the bath, it was set to 150° F. and switched on. When the temperature of the bath first reached 150° F., the experiment timer was started. A metering pump was used to add make-up DI water to the bath in attempt to hold the level as water evaporated from the bath. Make up flow was set at 8.5 mL/minute.

At the end of the experiment time, the water bath was turned off and the tubes were allowed to cool to a comfortable handling temperature before removal. The period at full-temperature was 162.75 hours.

Each tube was removed from the water bath in random order and cleaned externally by wiping with a Texwipe cleanroom wipe wetted with 10% (w/w) nitric acid prepared by diluting reagent grade material with DI water. The wipe process was used to remove scale and particulates left on the tube from the water bath. A second Texwipe was then used to dry the outside of the tube. The aluminum foil caps were removed and each tube was weighed to a resolution of 0.01 g.

After weighing, each tube was gently tipped laterally back and forth 3 times to cause the liquid in the tube to mix, and the then contents were decanted into a clean digestion vial for storage. The tubes were rinsed with reagent grade water and placed in an inverted position in a convection oven and baked in air at 80° C. for about 2 hours to dry them. After drying they were allowed to cool in the oven before being placed in polyethylene bags for storage.

Method of H₂O₂ Decomposition Calculation

The active oxygen loss (AOL) method used to calculate H₂O₂ decomposition was taken from FMC Technical Bulletin 104.

$$\begin{matrix}\% Active Oxygen Loss = \frac{{W}_{1} - {W}_{2}}{{CW}_{1} \times 0.47} \times 100 \\ {W}_{1} = Initial net weight \\ {W}_{2} = Final net weight \\ C = Initial fraction hydrogen peroxide ( \frac{\% concentrate}{100} )\end{matrix}$$

TABLE 1
Uncertainty in AOL Measurement

| Measure- | | Units of | Magnitude of | Sigma as % of |
|---|---|---|---|---|
| ment | Sigma | Measurement | Measurement | Measured value |
| W1 | 0.05 | Grams | 41 | 0.12% |
| W2 | 0.05 | Grams | 41 | 0.12% |
| C | .039⁽²⁾ | Weight % H₂O₂ | 92 | 0.042% |

| | |
|---|---|
| 1-Sigma as Combined Uncertainty | 0.175% |

### Active Oxygen Loss

Active oxygen loss is a measure of how much of the original concentration of H₂O₂ is lost during exposure of the peroxide to a material over a time period at temperature. A high active oxygen loss is undesirable, as it means the H₂O₂ is decomposing due to interactions with the material. A standard FMC test condition of 150° F. for 162.75 hours was used in this experiment (see Technical Data Bulletin 104, FMC Corporation, 1966).

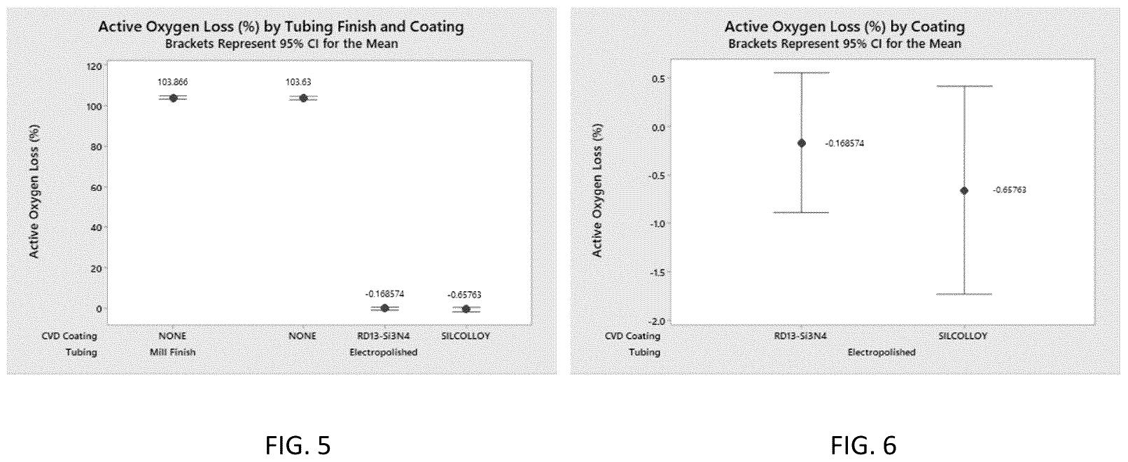

In both cases, as shown in FIGS. 5 and 6, the uncoated tubing experienced nearly total decomposition of the H₂O₂ (100% active oxygen loss), whereas both coated samples showed zero loss (within experimental error). As used herein, “nearly total decomposition” means decomposition that is below the limit of below the limit of detection by the refractometer which is 0.1 mass % H₂O₂.

Mass % H₂O₂ Remaining in Test Samples (U-Tubes)

The concentration of H₂O₂ remaining in the liquid after the time at temperature is another measurement of the effect of a material on the stability of the H₂O₂. The closer this concentration is to the starting concentration, the less the H₂O₂ has likely decomposed during the test. However, decomposing H₂O₂ produces water, which dilutes the remaining peroxide, so unless this is accounted for, this method is typically less accurate than then % AOL method. This experiment was not designed to account for dilution, as AOL was the primary decomposition metric. Concentration was determined from the fluid index of refraction, using the same conversions under the assumption that leachates in the H₂O₂ as a result of the test, would not significantly affect the measurements.

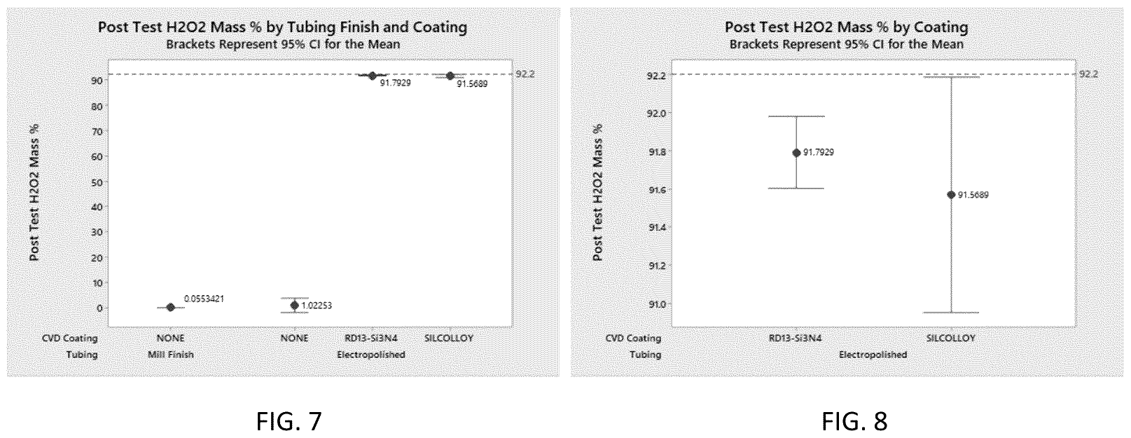

According to this test method, as shown in FIGS. 7 and 8, the uncoated tubes had very low levels of H₂O₂ remaining, with the mean value for the electropolished tube higher, but not statistically different than the mill finish at 95% confidence. The RD13-Si3N4 coated tube lost 0.41 mass % H₂O₂ and the Silcolloy tube lost 0.63 mass % H₂O₂. The results between these two coatings are not statistically different from each other at 95% confidence.

H₂O₂ Contamination and Leachates

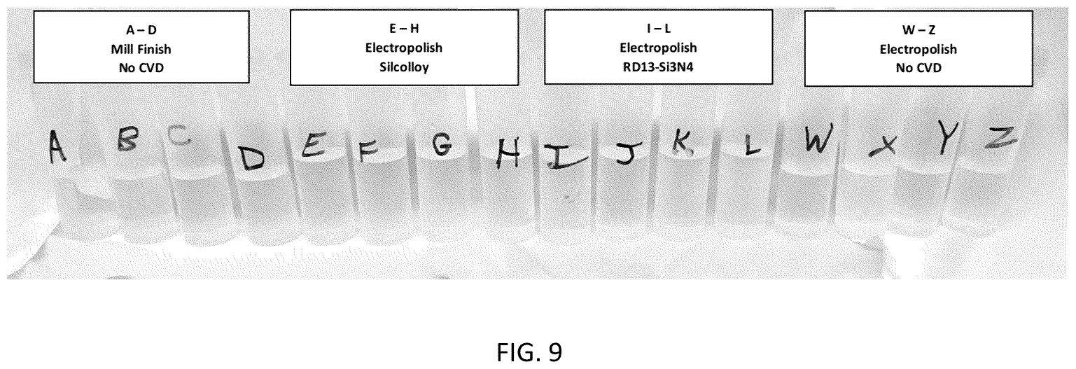

Fluid recovered from the uncoated U-tubes were contaminated with leachates to such a degree that the fluid was visibly colored. There was no visible color evident in fluid from any of the coated U-tubes. The fluid recovered in each test sample is illustrated in FIG. 9.

### Si, Cr, Fe and Ni Leachates

Total X-ray fluorescence spectroscopy (TXRF) was used to quantify metal ion contamination in the fluid samples. Detection limits for this technique are in the parts per billion range for the analytes considered.

The refractive index of all tube H₂O₂ samples was measured and samples from each tube, plus a sample of the initial 92% H₂O₂ were prepared for TXRF analysis. The TXRF preparation procedure was to weigh an aliquot of 100 ppm Ga standard of approximately 0.01 g and a sample of H₂O₂ of approximately 10 g using the analytical balance. Samples were mixed using a vibratory shaker and a 2.5 uL aliquot of each sample was deposited on a sapphire carrier heated to 75° C. Each carrier received 3 depositions of sample. TXRF analysis was conducted for 1000 seconds of live time for each sample.

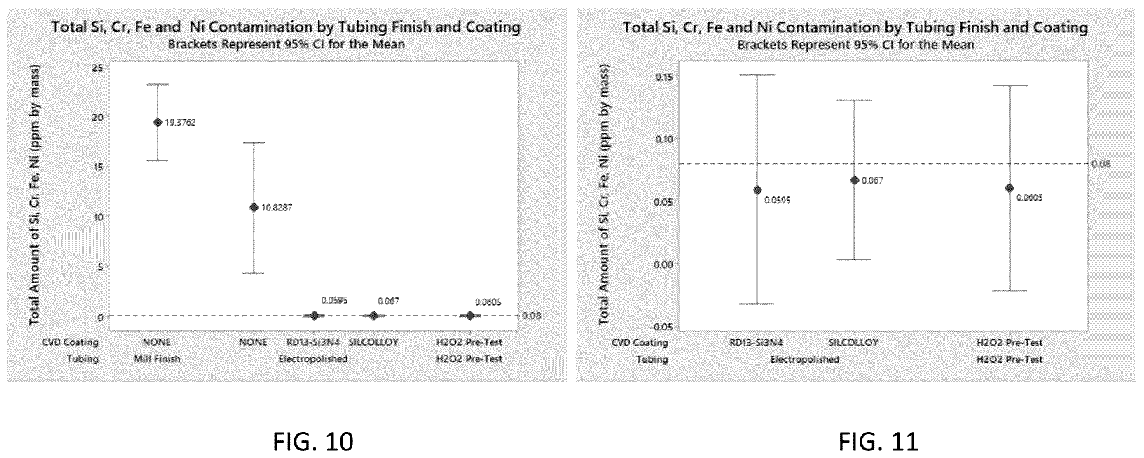

The sum of Si, Cr, Fe and Ni levels by coating type, and the pre-test H₂O₂ are shown in FIGS. 10 and 11. The uncoated U-tube samples were relatively heavily contaminated, being 125-240X above Evonik's product purity limits. The mean levels of contaminants in the coated tubes were statistically indistinguishable from the pre-test H₂O₂ at the 95% confidence level. The line at 0.08 ppm is approximately where the Evonik maximum allowable specification would be. Evonik does not have a specification for combined Si, Cr, Fe and Ni, but Cr, Fe and Ni are specified separately at 0.02 ppm each. Evonik does not specify maximum Si levels.

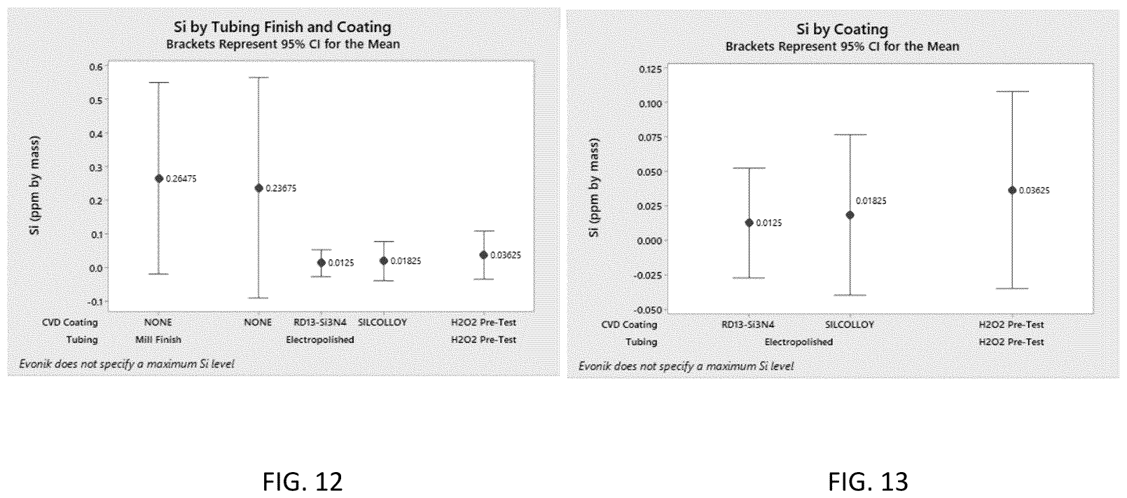

Silicon Leachates: The tests results for silicon leachates are shown in FIGS. 12 and 13: The uncoated tubes had higher Si levels leached into the H₂O₂ than the coated tubes, which had Si concentrations statistically equivalent to incoming H₂O₂.

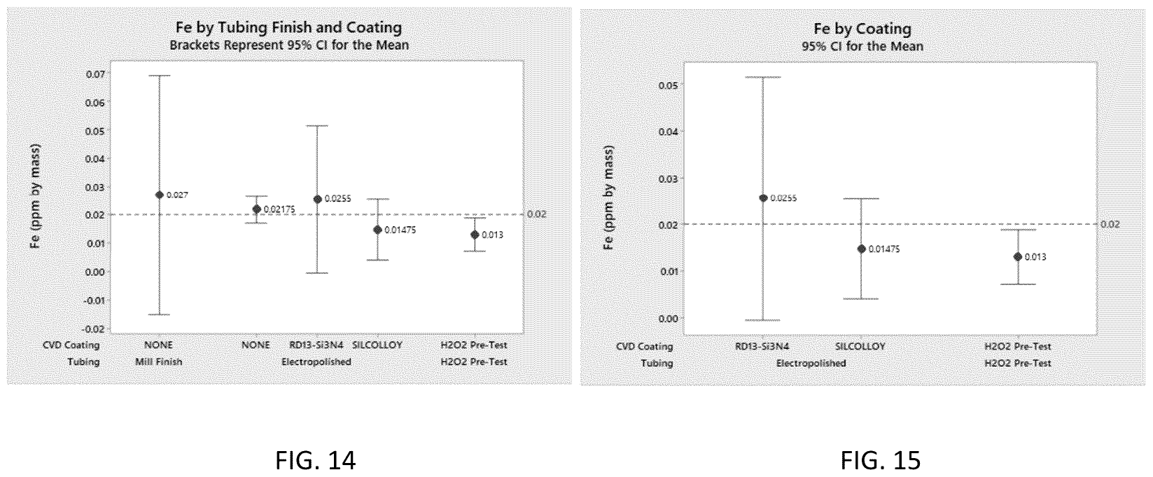

Iron Leachates: The tests results for iron leachates are shown in FIGS. 14 and 15: The passivation process used for all tubing was 3-4 hours at room temperature (25° C.) using 70% nitric acid, which is the FMC recommended process. In general, Fe leachates are near or below the Evonik specification of 0.02 ppm by mass for all experimental conditions. Electropolish of uncoated tubing appears to reduce the variation in Fe leachates, which is consistent with FMC data and recommended best practices for use of stainless steels with H₂O₂.

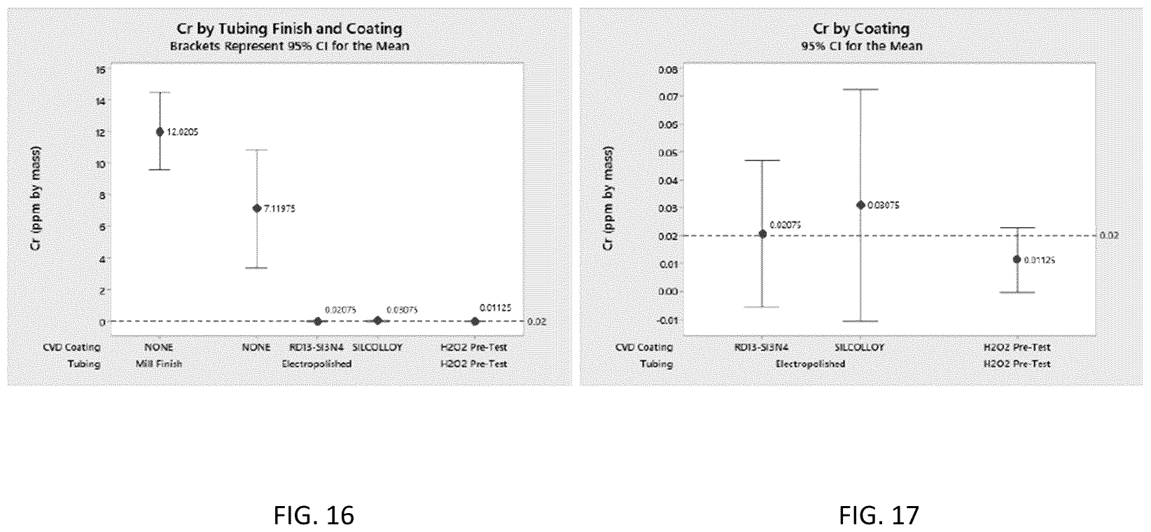

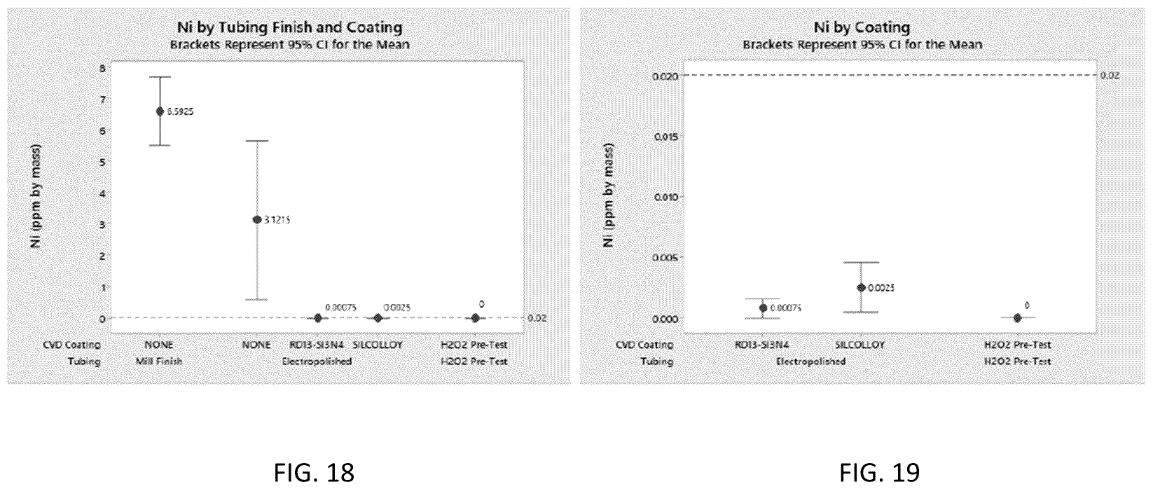

Chromium and Nickel Leachates: The chemical resistance of 316 SS is largely attributed to the Cr and Ni oxides on its surface. Thus, if appreciable Cr or Ni are leached from the material, it is indicative of failure of this mode of protection. The test results for chromium leachates are illustrated in FIGS. 16 and 17, and the test results for nickel leachates are illustrated in FIGS. 18 and 19.

The uncoated tubes clearly produced significant Cr and Ni leachates, which should cause concern regarding application of 316 SS for high concentration H₂O₂ service. Electropolishing reduced the Cr leachate by approximately 50% in uncoated tubing. Both CVD coatings allowed some Cr to leach into the H₂O₂, but the levels were as much as 600 times lower than uncoated 316 SS. Nickel leachates were also high in the uncoated tubing and as with Cr, electropolishing reduced the Ni levels by approximately 50% comparted to the mill finish tubes. For the CVD coated tubes, nickel levels remained quite low and within Evonik's specification for incoming H₂O₂.

### Corrosion Analysis of Tubing

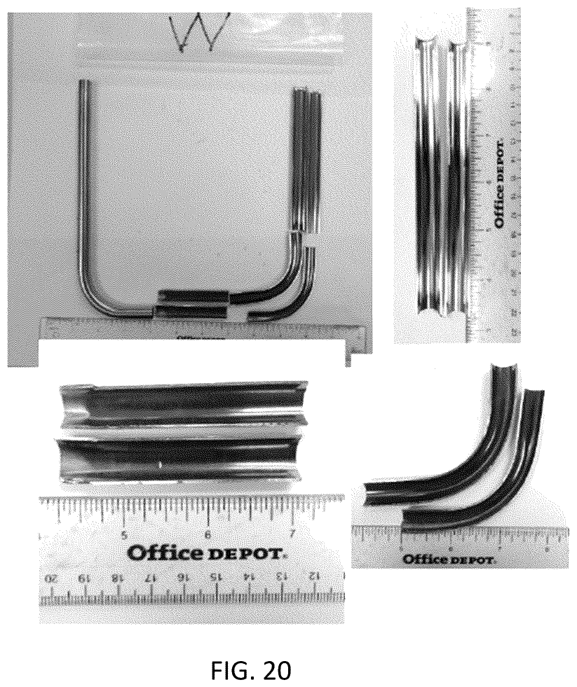

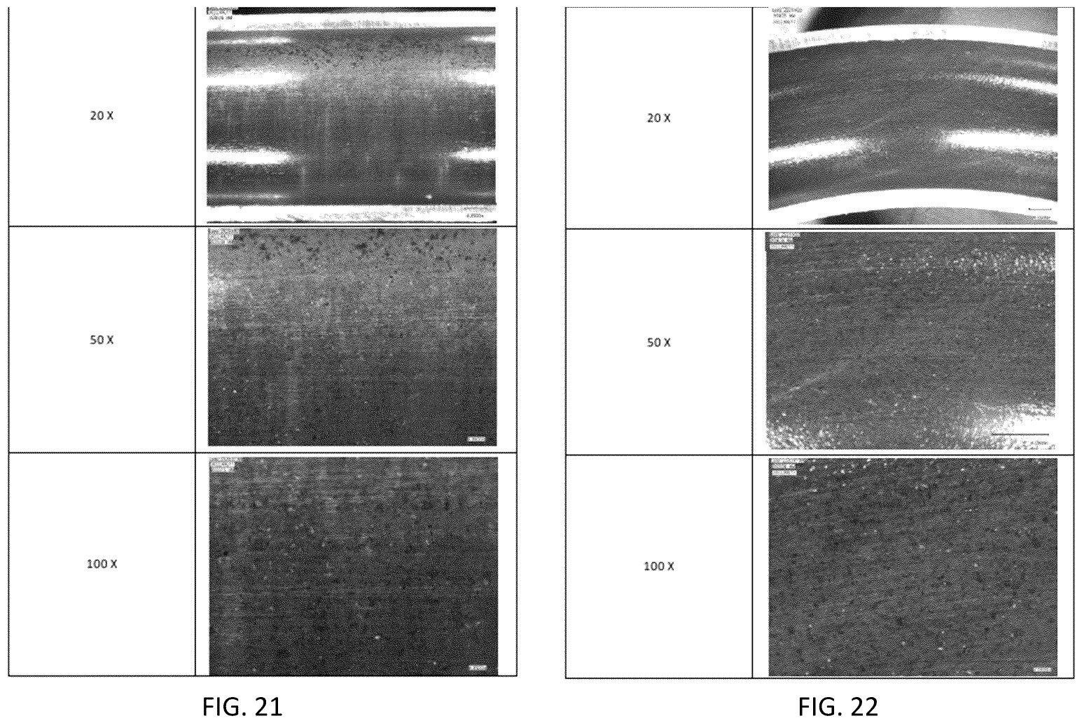

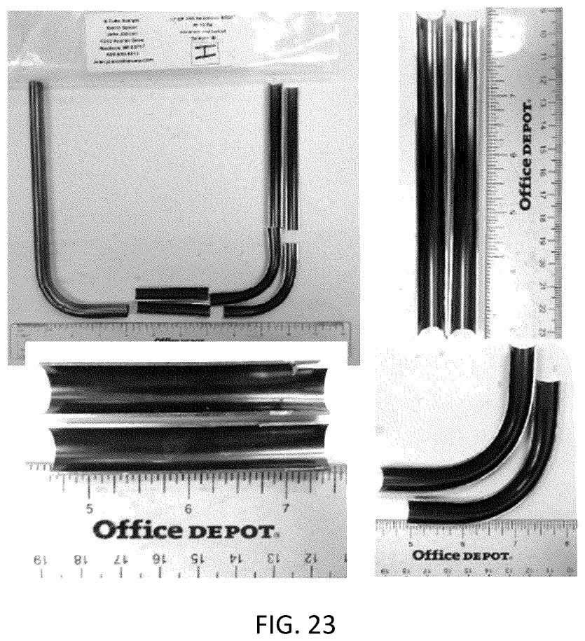

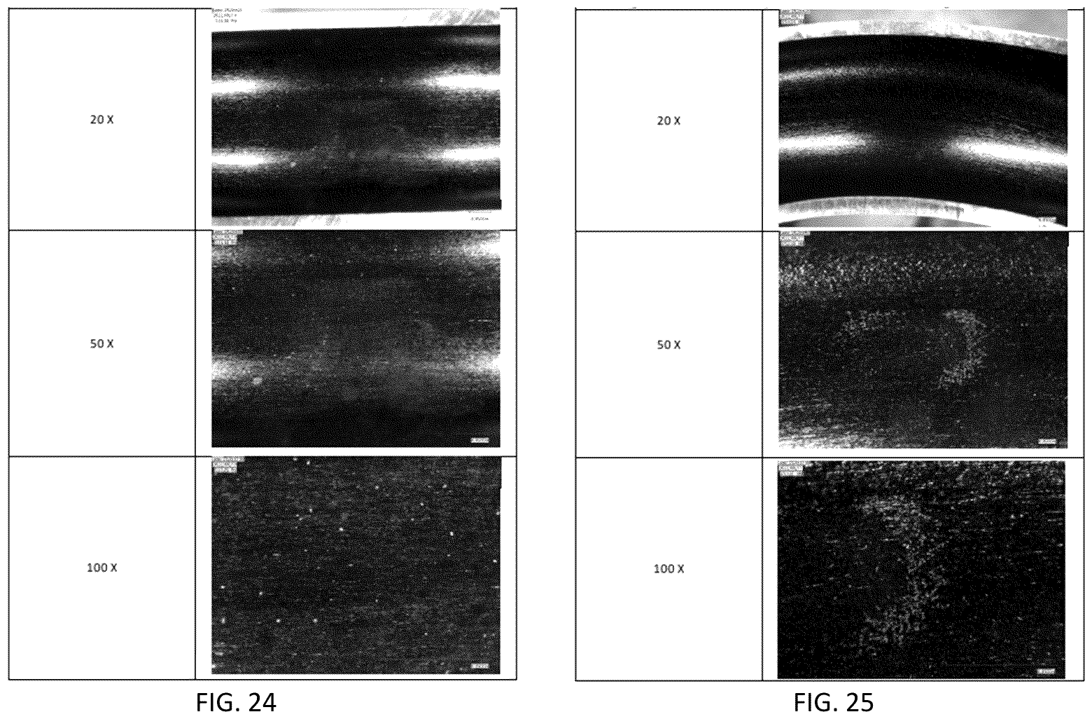

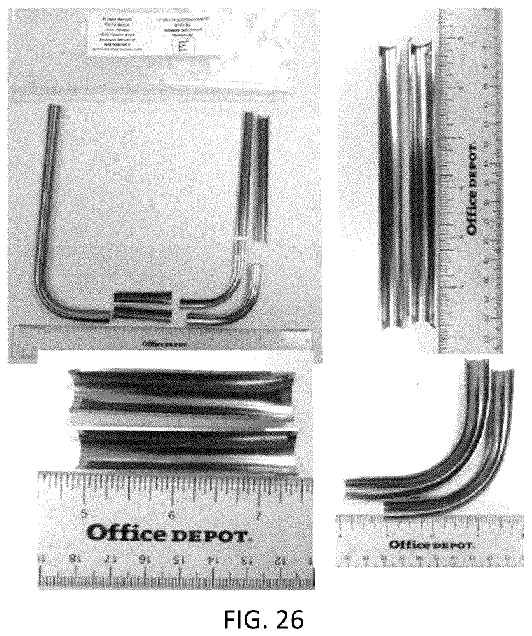

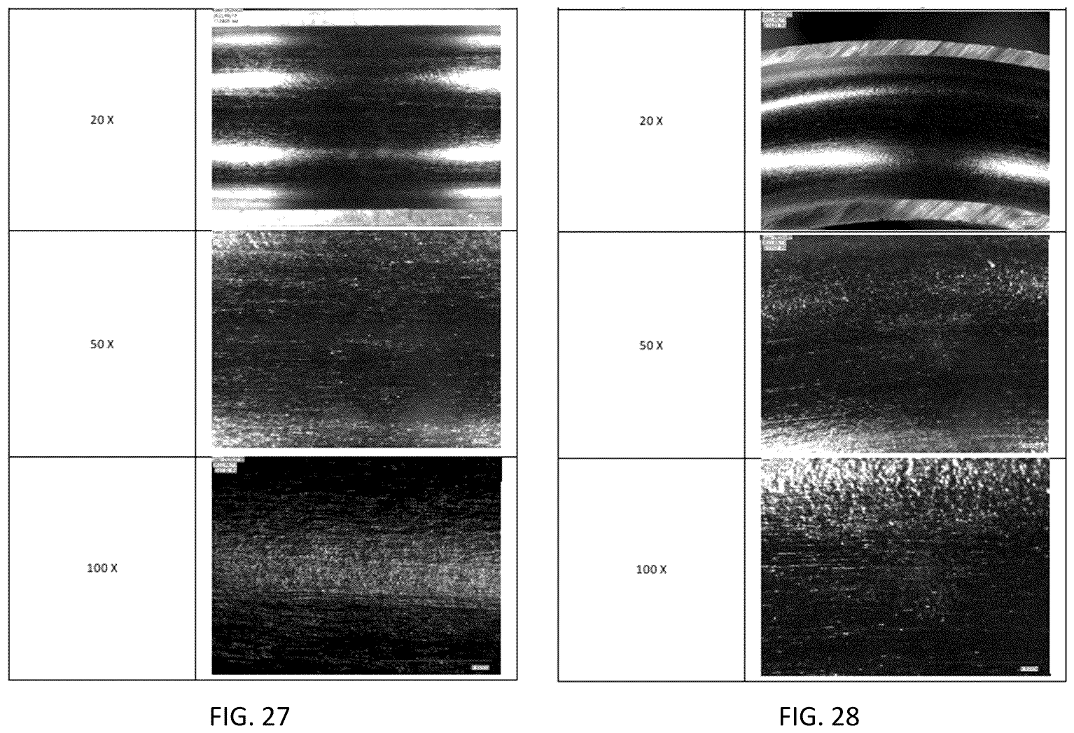

Three samples of the U-tubes where observed for corrosion after exposure to 92% by mass H₂O₂ at 150° F. for 162.75 hours. Visual observation and light microscopy were used to qualitatively assess corrosion. The three U-samples were as follows: Sample W (electropolished, but no barrier coating), Sample I (electropolished with RD13-silicon nitride coating), and Sample E (electropolished with Silcolly coating). FIGS. 20-23 illustrate Sample W after exposure, FIGS. 24-26 illustrate Sample I after exposure, and FIGS. 27-29 illustrate Sample after exposure. The uncoated tubing was corroded and “bronzed” on the inside throughout the wetted areas. Coated tubes had no visually observable internal corrosion. Corrosion was not observed above the liquid line in any tube.

The examples and illustrations included herein show, by way of illustration and not of limitation, specific embodiments in which the subject matter may be practiced. As mentioned, other embodiments may be utilized and derived there from, such that structural and logical substitutions and changes may be made without departing from the scope of this disclosure. Such embodiments of the inventive subject matter may be referred to herein individually or collectively by the term “invention” merely for convenience and without intending to voluntarily limit the scope of this application to any single invention or inventive concept, if more than one is, in fact, disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description. Use of the term “based on,” herein and in the claims is intended to mean, “based at least in part on,” such that an unrecited feature or element is also permissible.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail herein, other modifications or additions are possible. In particular, further features and/or variations can be provided in addition to those set forth herein. For example, the implementations described herein can be directed to various combinations and subcombinations of the disclosed features and/or combinations and subcombinations of several further features disclosed herein. In addition, the logic flows depicted in the accompanying figures and/or described herein do not necessarily require the particular order shown, or sequential order, to achieve desirable results. Other implementations may be within the scope of the following claims.

What is claimed is:

1. A method for storing an oxidizing substance, the method comprising,
storing or passing one or more oxidizing substances in or through a coated article, the coated article comprising,
a housing having an outer surface and an inner surface, and a barrier coating disposed onto at least a portion of the inner surface, the barrier coating comprising hydrogen-terminated silicon.

2. The method of claim 1, wherein the one or more oxidizing substances comprises hydrogen peroxide, hydroxylamine nitrate, deionized water, or any combination thereof.

3. The method of claim 2, where the housing comprises one or more ceramics.

4. The method of claim 3, wherein the housing comprises one or more polymers.

5. The method of claim 3, wherein the housing comprises one or more metals.

6. The method of claim 4, wherein the one or more metals comprise one or more metal alloys.

7. The method claim 4, wherein the one or more metals comprise stainless steel.

8. The method of claim 4, wherein the one or more metals comprise nickel alloys, zirconium alloys, niobium alloys, copper, or silver.

9. The method of claim 1, wherein the housing comprises at least one glass.

10. The method of claim 1, wherein the one or more oxidizing substances comprises hydrogen peroxide or hydroxylamine nitrate.

11. The method of claim 9, wherein the hydrogen peroxide is greater than or equal to 30 mass percent of the mixture.

12. The method of claim 9, wherein the hydrogen peroxide is greater than or equal to 92 mass percent of the mixture.

13. The method of claim 9, wherein the hydrogen peroxide is greater than or equal to 98 mass percent of the mixture.

14. The method of claim 12, wherein a decomposition rate of the hydrogen peroxide in the housing is equal to or less than 5 mass percent over at least 162 hours at 150° F.

15. The method of claim 12, wherein a decomposition rate of the hydrogen peroxide in the housing is from about 0.1 mass percent to 5 mass percent over at least 162 hours at 150° F.

16. The method of claim 12, wherein a decomposition rate of the hydrogen peroxide in the housing is equal to or less than 1 mass percent over at least 162 hours at 150° F.

17. The method of claim 12, wherein there is not more than 0.05 ppm of silicon present in the mixture over at least 162 hours at 150° F.

18. The method of claim 16, wherein there is not more than 0.05 ppm of iron present in the mixture over at least 162 hours at 150° F.

19. The method of claim 18, further comprising depositing the barrier coating onto the inner surface of the housing.

20. The method of claim 18, wherein the housing comprises a substrate, and wherein depositing the barrier coating comprises placing the substrate in a chamber, heating the substrate, introducing one or more precursors and one or more inert carrier sources into the chamber to allow the precursor and source to react to thereby form the barrier coating on at least one surface of the heated substrate, the at least one surface configured to contact hydrogen peroxide.
